(19) United States
(12) Patent Application Publication
(10) Pub. No.: US 2023/0063388 A1
(43) Pub. Date: Mar. 2, 2023

(54) SEMICONDUCTOR ARRANGEMENT AND METHOD OF MAKING

(71) Applicant: TAIWAN SEMICONDUCTOR MANUFACTURING COMPANY LIMITED, Hsin-Chu (TW)

(72) Inventors: Anhow CHENG, Taichung City (TW); Kuo FANG-TING, Zhubei City (TW)

(21) Appl. No.: 17/458,751

(22) Filed: Aug. 27, 2021

(51) Int. Cl. H01L 21/8238; H01L 27/092; H01L 29/49; H01L 21/28

(52) U.S. Cl. CPC H01L 21/823842; H01L 27/092; H01L 29/4966; H01L 21/28088

(57) ABSTRACT

A semiconductor arrangement is provided and includes a gate electrode. The gate electrode includes a first portion over a first interface between an active region and an isolation structure and a second portion over the active region. The first portion has a first material composition. The second portion has a second material composition different than the first material composition.

### BACKGROUND

In a semiconductor device, such as a transistor, current flows through a channel region between a source region and a drain region upon application of a sufficient voltage or bias to a gate of the device. The gate is isolated from the channel region by a gate dielectric layer. When current flows through the channel region, the device is generally regarded as being in an ‘on’ state, and when current is not flowing through the channel region, the device is generally regarded as being in an ‘off’ state.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-15 are illustrations of a semiconductor arrangement at various stages of fabrication, in accordance with some embodiments.

FIGS. 16-19 are illustrations of a semiconductor arrangement at various stages of fabrication, in accordance with some embodiments.

FIGS. 20-21 are illustrations of a semiconductor arrangement at various stages of fabrication, in accordance with some embodiments.

FIGS. 22-23 are illustrations of a semiconductor arrangement at various stages of fabrication, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

One or more techniques for fabricating a semiconductor arrangement are provided herein. A gate electrode is formed to have more than one portion. A first portion is over an interface between an active region and an isolation structure that bounds the active region. The second portion is over the active region, but not the interface. The first portion has a first material composition while the second portion has a second material composition, different than the first material composition. A material composition of the gate electrode affects an electromagnetic field that is generated in and around the active region when a voltage is applied to the gate electrode. The electromagnetic field, in turn, affects electrical current that flows through the active region. The active region is, at times, referred to as a channel. Current flow through the channel is generally regarded as flowing through the channel from a source region to a drain region. Accordingly, as provided herein, the different material compositions of the gate electrode afford a degree of control over electromagnetic fields generated in and around the channel, and thus a degree of control over current flowing through the channel.

Current flow at or near the interface between the active region and the isolation structure can be noisy and/or present other undesirable issues. At least some examples of noise include random telegraph signals or flicker in signals. Issues can arise at the interface at least because the isolation structure is not electrically conductive whereas the active region is electrically conductive. The electrical current flowing through the active region or channel can be analogous to fluids flowing through a medium. For example, water flowing in a river might be swift, predictable, etc. in a center of a river but might be slow, turbulent, unpredictable, etc. near the banks of the river. The same might be true for a fluid flowing through a pipe, where undesirable fluid dynamics might be experienced near an inner sidewall of the pipe. The interface between the active region and the isolation structure can be analogous to the banks of the river and/or the inner sidewall of the pipe in that issues can arise with current flow at or near the interface.

Accordingly, as provided herein, the different material compositions of the different portions of the gate electrode are selected so that current flow through the channel is inhibited at or near the interface between the active region and the isolation structure. Inhibiting current flow through the channel at or near the interface mitigates noise and/or other undesirable issues that might otherwise occur when current flow occurs at or near the interface. Mitigating noise and/or other undesirable issues at or near the interface improves performance of the resulting semiconductor arrangement.

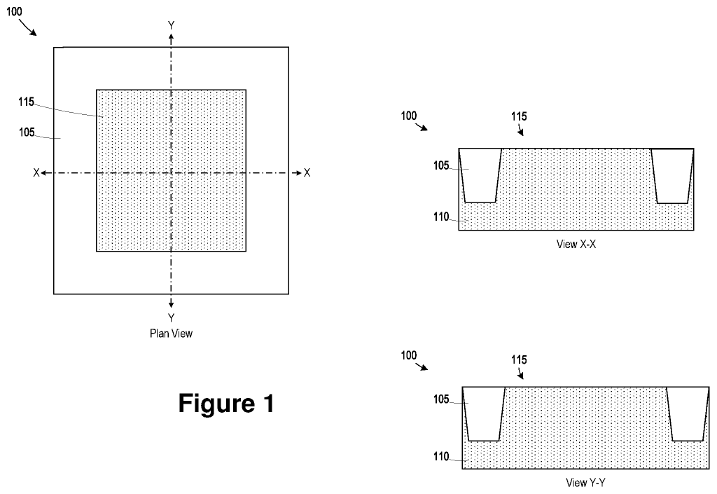

FIGS. 1-15 illustrate a semiconductor arrangement 100 at various stages of fabrication, in accordance with some embodiments. FIGS. 1-15 includes a plan view showing where various cross-sectional views are taken. The view X-X is a cross-sectional view taken through the semiconductor arrangement 100 in a direction corresponding to a gate length direction, and the view Y-Y is a cross-sectional view taken through the semiconductor arrangement 100 in a direction corresponding to a gate width direction. Not all aspects of the processing shown in the cross-sectional views are depicted in the plan view.

Referring to FIG. 1, a shallow trench isolation (STI) structure 105 is formed in a semiconductor layer 110. An active region 115, such as a channel, of the semiconductor layer 110 is bounded by the STI structure 105. In some embodiments, the semiconductor layer 110 is part of a substrate comprising at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, and InP, a silicon-on-insulator (SOI) structure, a wafer, or a die formed from a wafer. In some embodiments, the semiconductor layer 110 comprises at least one of crystalline silicon or other suitable materials. Other structures and/or configurations of the semiconductor layer 110 are within the scope of the present disclosure.

In some embodiments, the STI structure 105 is formed by forming at least one mask layer over the semiconductor layer. In some embodiments, the mask layer comprises a layer of oxide material over the semiconductor layer 110 and a layer of nitride material over the layer of oxide material, and/or one or more other suitable layers. At least some of the layer of mask layer is removed to define an etch mask for use as a template to etch the semiconductor layer 110 to form a trench. A dielectric material is formed in the trench to define the STI structure 105. In some embodiments, the STI structure 105 includes multiple layers, such as an oxide liner, a nitride liner formed over the oxide liner, an oxide fill material formed over the nitride liner, and/or other suitable materials.

In some embodiments, a fill material is formed using a high density (HDP) plasma process. The HDP process uses precursor gases comprising at least one of silane (SiH4), oxygen, argon, or other suitable gases. The HDP process includes a deposition component, which forms material on surfaces defining the trench, and a sputtering component, which removes or relocates deposited material. A deposition-to-sputtering ratio depends on gas ratios employed during the deposition. According to some embodiments, Argon and oxygen act as sputtering sources, and the particular values of the gas ratios are determined based on an aspect ratio of the trench. After forming the fill material, an anneal process is performed to densify the fill material. In some embodiments, the STI structure 105 generates compressive stress that serves to compress the active region 115. Other structures and/or configurations of the STI structure 105 are within the scope of the present disclosure.

Although the semiconductor layer 110 and the STI structure 105 are illustrated as having coplanar upper surfaces at an interface 120 where the semiconductor layer 110 abuts the STI structure 105, the relative heights can vary. For example, the STI structure 105 can be recessed relative to the semiconductor layer 110 or the semiconductor layer 110 can be recessed relative to the STI structure 105. The relative heights at the interface 120 depend on the processes performed for forming the STI structure 105, such as at least one of deposition, planarization, mask removal, surface treatment, or other suitable techniques.

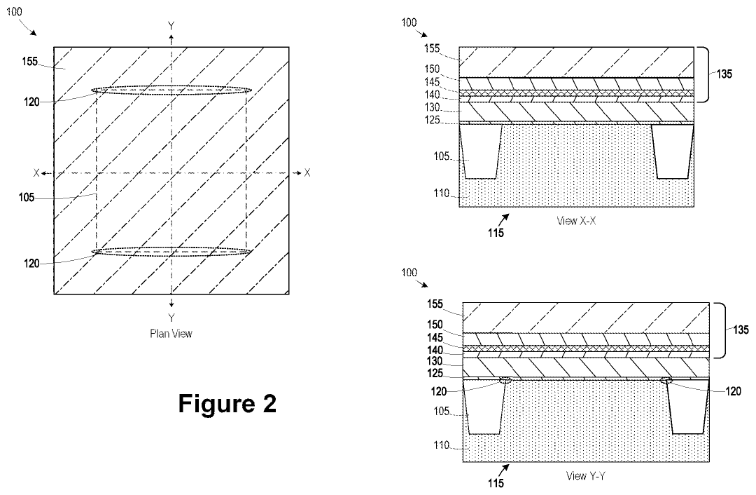

Referring to FIG. 2, a plurality of layers is formed over the semiconductor layer 110, in accordance with some embodiments. A gate dielectric layer 125 is formed over the STI structure 105 and the semiconductor layer 110. The gate dielectric layer 125 is formed by at least one of thermal oxidation, chemical oxidation, chemical vapor deposition (CVD), low pressure CVD (LPCVD), plasma enhanced CVD (PECVD), ultra-high vacuum CVD (UHVCVD), reduced pressure CVD (RPCVD), atomic layer deposition (ALD), physical vapor deposition, pulsed laser deposition, sputtering, evaporative deposition, vapor phase epitaxy (VPE), molecular beam epitaxy (MBE), liquid phase epitaxy (LPE), spin-on, growth, or other suitable techniques. In some embodiments, the gate dielectric layer 125 comprises nitride, oxide, and/or other suitable materials. Other structures and/or configurations of the gate dielectric layer 125 are within the scope of the present disclosure.

In some embodiments, a gate electrode layer 130 is formed over the gate dielectric layer 125 by at least one of CVD, LPCVD, PECVD, UHVCVD, RPCVD, ALD, physical vapor deposition, pulsed laser deposition, sputtering, evaporative deposition, VPE, MBE, LPE, spin-on, growth, or other suitable techniques. In some embodiments, the gate electrode layer 130 comprises polysilicon and/or other suitable materials. Other structures and/or configurations of the gate electrode layer 130 are within the scope of the present disclosure.

A first mask layer 135 is formed over the gate electrode layer 130. According to some embodiments, the first mask layer 135 comprises a plurality of individually formed layers that together define a first mask stack. In some embodiments, the first mask layer 135 comprises one or more of a hard mask layer 140, a bottom antireflective coating (BARC) layer 145 formed over the hard mask layer 140, an organic planarization layer (OPL) 150 formed over the BARC layer 145, a photoresist layer 155 formed over the OPL 150, and/or other suitable layers. Other structures and/or configurations of the first mask layer 135 are within the scope of the present disclosure.

In some embodiments, the hard mask layer 140 is formed by at least one of CVD, LPCVD, PECVD, UHVCVD, RPCVD, ALD, physical vapor deposition, pulsed laser deposition, sputtering, evaporative deposition, VPE, MBE, LPE, spin-on, growth or other suitable techniques. In some embodiments, the hard mask layer 140 comprises silicon, nitrogen and/or other suitable materials. Other structures and/or configurations of the hard mask layer 140 are within the scope of the present disclosure.

In some embodiments, the BARC layer 145 is a polymer and/or other layer applied using a spin coating and/or other suitable technique. Other structures and/or configurations of the BARC layer 145 are within the scope of the present disclosure.

In some embodiments, the OPL 150 comprises a photo-sensitive organic polymer that is applied using a spin coating and/or other suitable techniques. In some embodiments, the OPL 150 comprises a dielectric material and/or other suitable materials. Other structures and/or configurations of the OPL 150 are within the scope of the present disclosure.

In some embodiments, the photoresist layer 155 is formed by at least one of spinning, spray coating, or other suitable techniques. The photoresist layer 155 comprises electromagnetic radiation sensitive and/or other materials. Properties, such as solubility, of the photoresist layer 155 are affected by electromagnetic radiation. The photoresist layer 155 is either a negative photoresist or a positive photoresist. Other structures and/or configurations of the photoresist layer 155 are within the scope of the present disclosure.

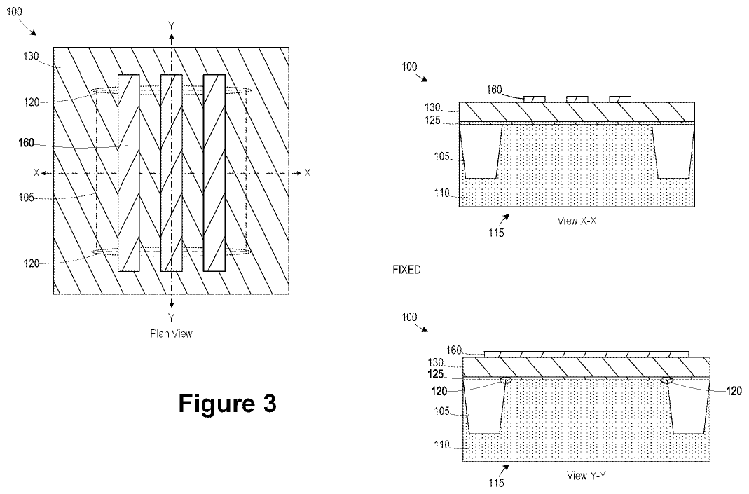

Referring to FIG. 3, the first mask layer 135 is patterned to define a gate mask 160, in accordance with some embodiments. In some embodiments, the photoresist layer 155 is exposed using a radiation source and a reticle to define a pattern in the photoresist layer 155. Portions of the patterned photoresist layer 155 are removed and the patterned photoresist layer 155 acts as a template for etching exposed portions of the OPL 150, BARC layer 145, and hard mask layer 140. In some embodiments, remaining portions of the photoresist layer 155, OPL 150, and BARC layer 145 are removed and remaining portions of the hard mask layer 140 define the gate mask 160.

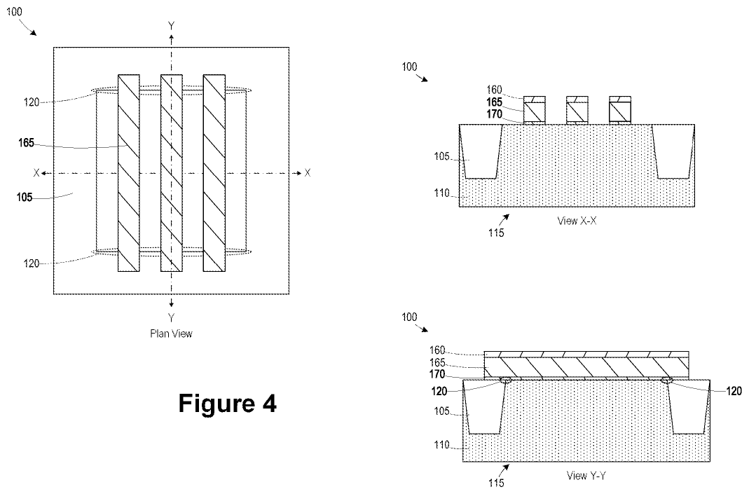

Referring to FIG. 4, gate electrodes 165 and gate dielectric layers 170 are formed over the active region 115, according to some embodiments. An etching processes is performed using the gate mask 160 as an etch template to pattern the gate electrode layer 130 and gate dielectric layer 125 to define the gate electrodes 165 and gate dielectric layers 170. In some embodiments, the etching process is at least one of a plasma etching process, a reactive ion etching (RIE) process, or other suitable techniques. In some embodiments, the chemistry of the etching process may be changed from a first etch chemistry for etching the gate electrode layer 130 and a second etch chemistry for etching the gate dielectric layer 125. In some embodiments, the gate mask 160 remains over the gate electrodes 165 and functions as a cap layer. Other configurations of the gate electrodes 165 and/or gate dielectric layers 170 are within the scope of the present disclosure. For ease of illustration, the gate mask 160 is omitted in the plan view.

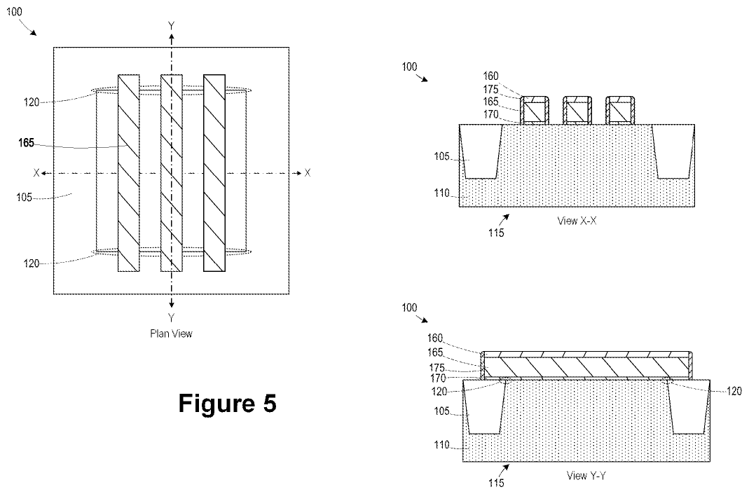

Referring to FIG. 5, sidewall spacers 175 are formed adjacent the gate mask 160, the gate electrodes 165, and the gate dielectric layers 170, according to some embodiments. In some embodiments, the sidewall spacers 175 are formed by depositing a conformal spacer layer over the gate mask 160, the gate electrodes 165, and the gate dielectric layers 170 and performing an anisotropic etch process to remove portions of the spacer layer positioned on horizontal surfaces of the gate mask 160, the semiconductor layer 110, and the STI structure 105. In some embodiments, the sidewall spacers 175 comprise the same material composition as the gate mask 160. In some embodiments, the sidewall spacers 175 comprise nitrogen, silicon and/or other suitable materials. Other structures and/or configurations of the sidewall spacers 175 are within the scope of the present disclosure. For ease of illustration, the sidewall spacers 175 are omitted from the plan view.

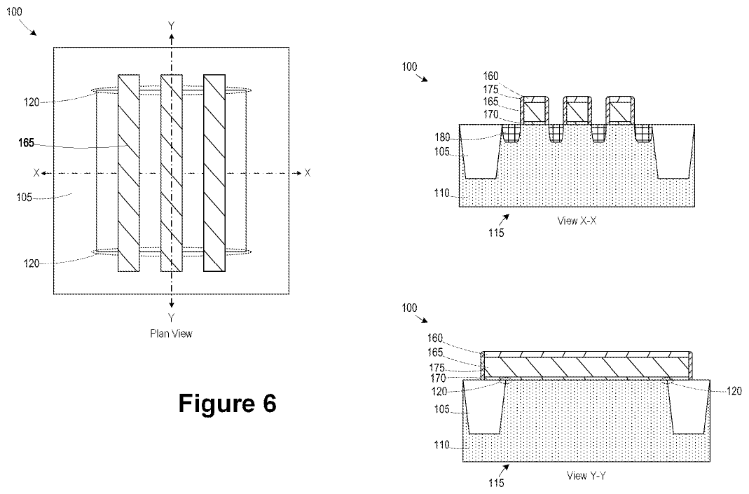

Referring to FIG. 6, source/drain regions 180 are formed in the semiconductor layer 110 adjacent the sidewall spacers 175. In some embodiments, an etch process is performed to recess the semiconductor layer 110 adjacent the sidewall spacers 175 and an epitaxial growth process is performed to form the source/drain regions 180. In some embodiments, the source/drain regions 180 are formed by implantation of dopants, also referred to as impurities, into the semiconductor layer 110 using the sidewall spacers 175 and the gate mask 160 as an implantation template. In some embodiments, such as where a resulting transistor is an n-type metal-oxide-semiconductor (nMOS) device, the source/drain regions 180 comprise an n-type impurity, such as at least one of phosphorous, arsenic, or other suitable n-type dopants, and the active region 115 includes a p-type dopant, such as at least one of boron, BF₂, or other suitable p-type dopants. In some embodiments, such as where a resulting transistor is a p-type metal-oxide-semiconductor (pMOS) device, the source/drain regions 180 comprise a p-type impurity, and the active region 115 includes an n-type dopant. In some embodiments, one or more implantation process are performed to tailor the dopant profiles of the source/drain regions 180. For example, a tilted implantation using a dopant having a conductivity type opposite the conductivity type of the dopant in the source/drain regions 180 is implanted under the sidewall spacers 175 to form halo regions, according to some embodiments. In some embodiments, an implantation process is performed to form a lightly doped region under the sidewall spacers 175. Other structures and/or configurations of the source/drain regions 180 are within the scope of the present disclosure. For ease of illustration, the source/drain regions 180 are omitted from the plan view.

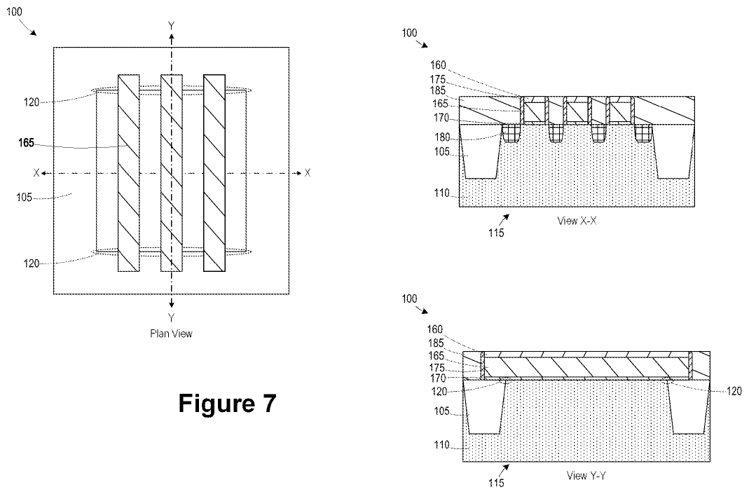

Referring to FIG. 7, a dielectric layer 185 is formed over the gate mask 160, sidewall spacers 175, STI structures 105, and source/drain regions 180, according to some embodiments. In some embodiments, the dielectric layer 185 is planarized to expose the gate mask 160. In some embodiments, the dielectric layer 185 comprises at least one of silicon dioxide, a low-k material, or other suitable materials. In some embodiments, the dielectric layer 185 comprises one or more layers of low-k dielectric material. Low-k dielectric materials have a k-value (dielectric constant) lower than about 3.9. Some low-k dielectric materials have a k-value lower than about 3.5 and may have a k-value lower than about 2.5. The materials for the dielectric layer 185 comprise at least one of Si, O, C, H, SiCOH, SiOC, nitrogen, polymers, a carbon-containing material, organo-silicate glass, a porogen-containing material, or other suitable materials. The dielectric layer 185 is formed using CVD, LPCVD, PECVD, UHVCVD, RPCVD, ALD, physical vapor deposition, pulsed laser deposition, sputtering, evaporative deposition, VPE, MBE, LPE, spin-on, growth, and/or other suitable techniques. Other structures and/or configurations of the dielectric layer 185 are within the scope of the present disclosure. For ease of illustration, the dielectric layer 185 is omitted from the plan view.

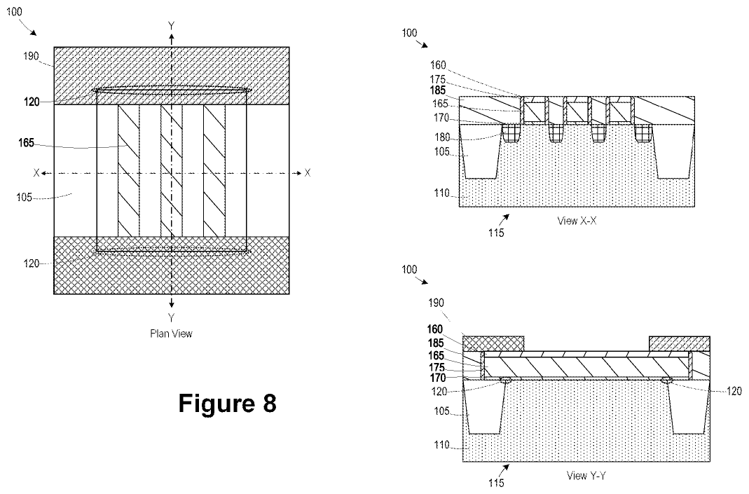

Referring to FIG. 8, a mask 190 is formed over end portions of the gate mask 160 positioned over the interface 120, according to some embodiments. In some embodiments, the mask 190 is formed using at least one of a hard mask layer, a BARC layer, an OPL, or a photoresist layer comprising materials and formed as described herein.

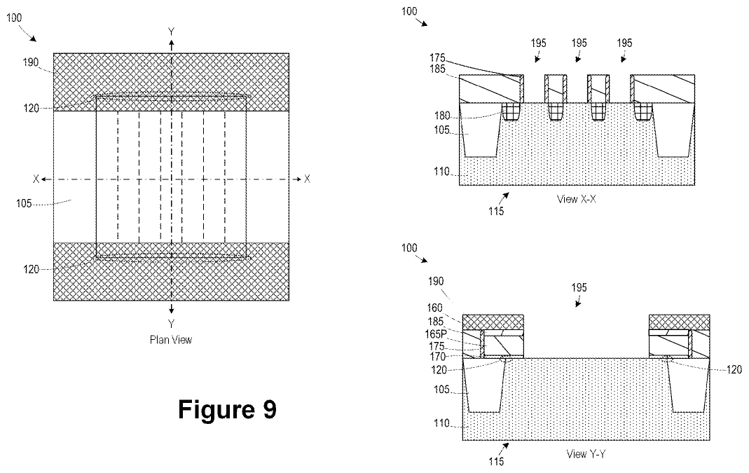

Referring to FIG. 9, portions of the gate mask 160, portions of the gate electrodes 165, and portions of the gate dielectric layers 170 are removed to define first gate cavities 195, according to some embodiments. At least one etching process is performed using the mask 190 as an etch template to remove the portions of the gate mask 160, the gate electrodes 165, and the gate dielectric layers 170 not covered by the mask 190 to define the first gate cavities 195 and remaining gate electrode portions 165P.

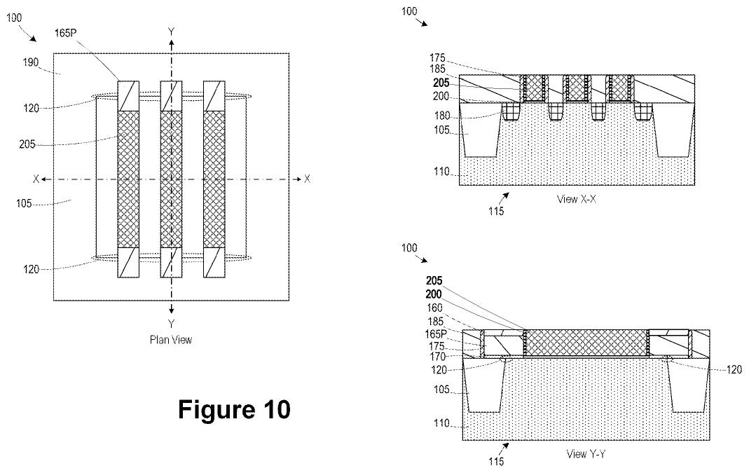

Referring to FIG. 10, the mask 190 is removed, gate dielectric layer 200 is formed in the first gate cavities 195, and gate electrode portions 205 are formed in the first gate cavities 195 over the gate dielectric layer 200, in accordance with some embodiments. In some embodiments, the gate dielectric layer 200 comprises a high-k dielectric layer. As used herein, the term “high-k dielectric” refers to the material having a dielectric constant, k, greater than about 3.9, which is the k value of SiO₂. Examples of the material of the high-k dielectric layer include at least one of Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiₓN_{y}, ZrO₂/Al₂O₃/ZrO₂, Al₂O₃/ZrO₂/Al₂O₃, ZrO₂/Al₂O₃/ZrO₂/Al₂O₃, a silicate thereof, an alloy thereof, or other suitable materials. Values of x vary independently from 0.5 to 3, and values of y vary independently from 0 to 2. In some embodiments, the gate electrode portions 205 comprise any number of suitable layers in a metal gate stack. In some embodiments, the metal gate stack comprises a work function material (WFM) layer. Example p-type work function metals include Mo, Ru, Ir, Pt, PtSi, MoN, TiN, Al, W, HfN, WN, NiSiₓ, ZrSi₂, MoSi₂, and/or TaSi₂. At least some p-type work function materials have work functions greater than about 4.5. Example n-type work function metals include Ti, Al, Ta, ZrSi₂, Ag, TaN, TaAl, TaAlC, TiAlN, TaC, TaCN, TaSiN, TaSiₓ, Mn, and/or Zr. At least some n-type work function materials have work functions less than about 4.5. The WFM layer may comprise a plurality of layers. In some embodiments, a barrier layer is formed prior to the formation of WFM layer. The WFM layer is formed by at least one of CVD, PVD, electroplating, or other suitable techniques. In some embodiments, the metal gate stack comprises a fill layer. In some embodiments, the fill layer comprises at least one of tungsten (W) or other suitable materials. The fill layer may be formed by at least one of ALD, PVD, CVD, or other suitable techniques. According to some embodiments, a planarization process is performed to remove portions of the material forming the gate electrode portions 205 and the gate dielectric layer 200 outside the first gate cavities 195. For ease of illustration the gate dielectric layer 200 is not illustrated in the plan view. Other structures and/or configurations of the gate electrode portions 205 and/or the gate dielectric layer 200 are within the scope of the present disclosure.

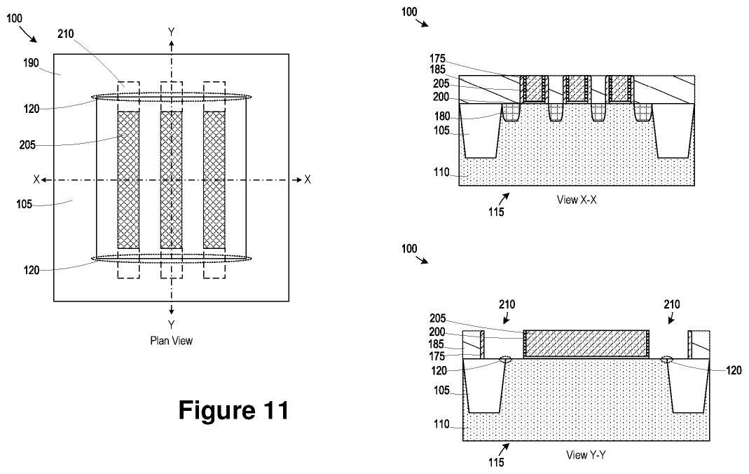

Referring to FIG. 11, remaining portions of the gate mask 160, the gate electrode portions 165P, and the gate dielectric layers 170 are removed to define second gate cavities 210, according to some embodiments. The second gate cavities 210 are positioned over the interface 120. At least one etching process is performed to remove the portions of the gate mask 160, the gate electrode portions 165P, and the gate dielectric layers 170 to define the second gate cavities 210.

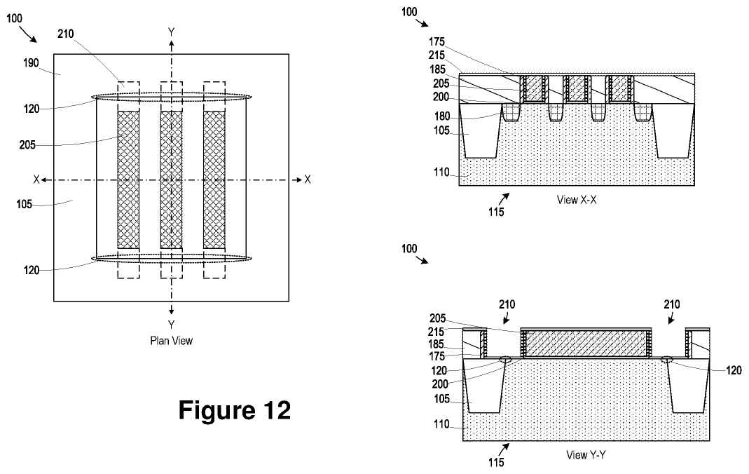

Referring to FIG. 12, gate dielectric layer 215 is formed in the second gate cavities 210 and over the dielectric layer 185 and the gate electrode portions 205, in accordance with some embodiments. In some embodiments, the gate dielectric layer 215 comprises a same material as the gate dielectric layer 200 and is formed using the processes and materials described herein. In some embodiments, the gate dielectric layer 215 comprises a different material than the gate dielectric layer 200. For ease of illustration the gate dielectric layer 215 is not illustrated in the plan view.

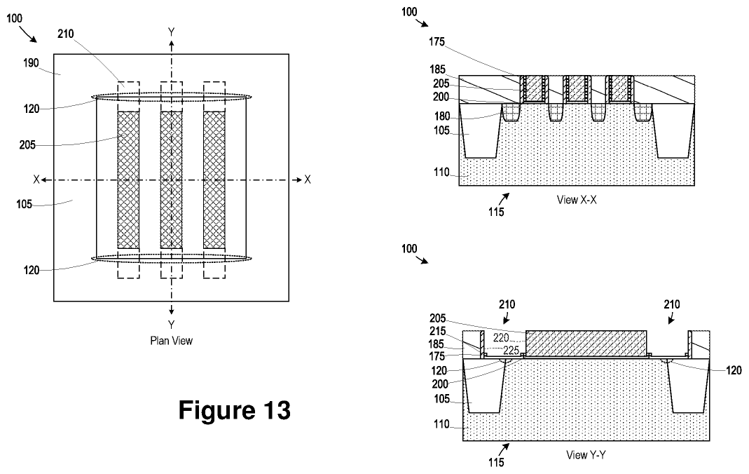

Referring to FIG. 13, the gate dielectric layer 215 is removed such that merely portions of the gate dielectric layer 215 remain in the second gate cavities 210, and portions of the gate dielectric layer 200 remaining on ends 220 of the gate electrode portions 205 after the second gate cavities 210 are formed are removed as well. In some embodiments, a chamfering process is performed to remove portions of the gate dielectric layer 215 from sidewalls 225 of the sidewall spacers 175 and/or to remove the portions of the gate dielectric layer 200 from the ends 220 of the gate electrode portions 205. According to some embodiments, a chamfering process includes depositing a sacrificial material in the second gate cavities 210, performing an etching process selective to the sacrificial material to expose the portions of the gate dielectric layer 200 and/or the gate dielectric layer 215 to be removed, performing an etching process selective to the material of the gate dielectric layer 200 and/or the gate dielectric layer 215 to remove exposed portions of the gate dielectric layer 200 and/or the gate dielectric layer 215, and performing an etching and/or ashing process to remove the sacrificial material. Other structures and/or configurations of the gate dielectric layer 200 and/or the gate dielectric layer 215 are within the scope of the present disclosure.

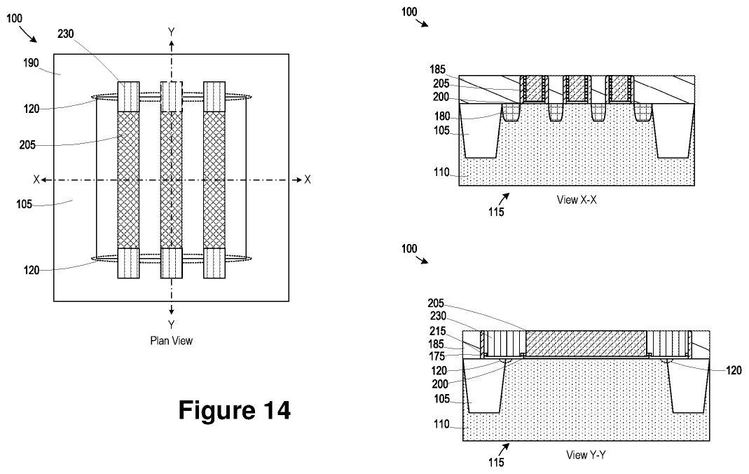

Referring to FIG. 14, gate electrode portions 230 are formed in the second gate cavities 210 over the gate dielectric layer 215, in accordance with some embodiments. In some embodiments, the gate electrode portions 230 comprise any number of suitable layers in a metal gate stack. In some embodiments, the metal gate stack comprises a work function material (WFM) layer of opposite conductivity type compared to the conductivity type of the gate electrode portions 205. For example, in an embodiment where the WFM of the gate electrode portions 205 is p-type, the WFM of the gate electrode portions 230 is n-type. Conversely, in an embodiment where the WFM of the gate electrode portions 205 is n-type, the WFM of the gate electrode portions 230 is p-type. The WFM layer in the gate electrode portions 230 may comprise a plurality of layers. In some embodiments, a barrier layer is formed prior to the formation of WFM layer. The WFM layer is formed by at least one of CVD, PVD, electroplating, or other suitable techniques. In some embodiments, the metal gate stack comprises a fill layer. In some embodiments, the fill layer comprises tungsten (W) and/or other suitable materials. The fill layer may be formed by at least one of ALD, PVD, CVD, or other suitable techniques. According to some embodiments, a planarization process is performed to remove portions of the material forming the gate electrode portions 230 outside the second gate cavities 210. In some embodiments, the ends 220 of the gate electrode portions 205 directly contact the gate electrode portions 230. Other structures and/or configurations of the gate electrode portions 205 and/or the gate electrode portions 230 are within the scope of the present disclosure.

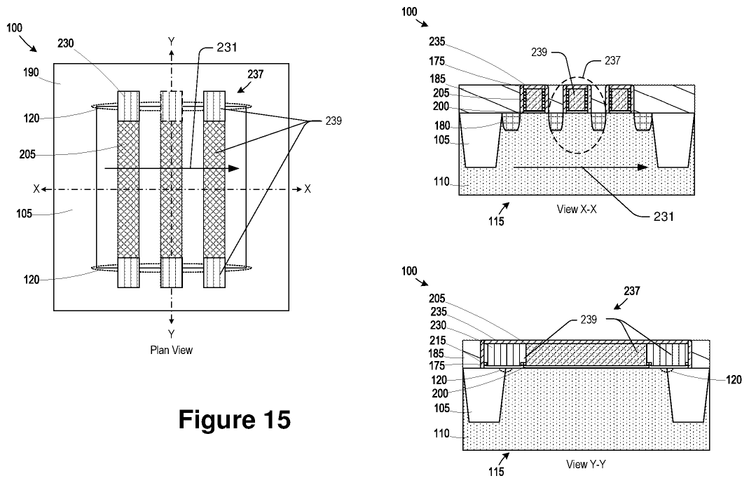

Referring to FIG. 15, cap layers 235 are formed over the gate electrode portions 205 and the gate electrode portions 230, according to some embodiments. In some embodiments, an etching process is performed to recess the gate electrode portions 205 and the gate electrode portions 230, a deposition process is performed to form the cap layers 235, and a planarization process is performed to remove portions of the cap layers 235 over the dielectric layer 185. In some embodiments, the cap layers 235 comprise silicon, nitrogen, oxygen, and/or other suitable materials. Other structures and/or configurations of the cap layers 235 are within the scope of the present disclosure. For ease of illustration, the cap layers 235 are omitted in the plan view.

In some embodiments, the gate dielectric layers 170 (FIG. 4) comprise high-k materials and the gate replacement processes described above merely remove the material of the gate electrode portions 165P prior to forming the gate electrode portions 205 and the gate electrode portions 230, thereby omitting the forming of the gate dielectric layer 200 in FIG. 10, the forming of the gate dielectric layer 215 in FIG. 12, and the chamfering process of FIG. 13.

As illustrated in FIG. 15, in some embodiments, a transistor 237 generally comprises a gate electrode 239, two source/drain regions 180, and a portion of the active region 115, also known as a channel, under the gate electrode 239 and between the two source/drain regions 180. The plan and Y-Y views in FIG. 15 illustrate that, according to some embodiments, the gate electrode 239 comprises a gate electrode portion 230 over an interface 120 between the active region 115 and an STI structure 105 and a gate electrode portion 205 over the active region 115. According to some embodiments, current flows through the channel in a direction indicated by arrow 231 in FIG. 15. Note that the direction of current flow is into the page in view Y-Y in FIG. 15.

According to some embodiments, a transistor is regarded as having multiple gate electrodes, instead of a single gate electrode. In such an embodiment, current flows in the active region 115 under more than one gate electrode, and a source/drain region 180 acts as a source relative to one gate electrode and a drain relative to another (adjacent) gate electrode. Although three gate electrodes 239 are illustrated in FIG. 15, any number of gate electrodes are contemplated.

According to some embodiments, the gate electrode portions 230 comprise materials having different work functions than the work functions of the materials of the gate electrode portions 205. In some embodiments, the work function of the gate electrode portions 205 is tailored to the conductivity type of transistor 237, and the work function of the gate electrode portions 230 is opposite the work function of the gate electrode portions 205. For example, if the transistor 237 comprises an n-type device, the gate electrode portions 205 comprise materials having an n-type work function, and the gate electrode portions 230 comprise materials having a p-type work function. Conversely, if the transistor 237 comprises a p-type device, the gate electrode portions 205 comprise materials having a p-type work function, and the gate electrode portions 230 comprise materials having an n-type work function. In some embodiments, the semiconductor arrangement 100 comprises both n-type and p-type transistors 237.

The material types and thus the work functions of the gate electrode portions 205 and the gate electrode portions 230 affect an electromagnetic field generated when a voltage is applied to the gate electrode 239. The electromagnetic field, in turn, affects the current that flows in the active region 115, such as through a channel from a source region to a drain region. Accordingly, controlling the material types and work functions of the gate electrode 239 affords a degree of control over the current flowing in the active region 115. According to some embodiments, the material types of the gate electrode portions 205 and the gate electrode portions 230 are selected such that less current flows in the active region 115 near the interface 120 relative to an amount of current that flows in the active region 115 away from the interface 120. Given that undesirable issues, such as noise, may result from current flow at or near the interface 120, reducing current flow at or near the interface 120 mitigates the undesirable issues and improves performance of a resulting semiconductor arrangement, such as the transistor 237. Other structures and/or configurations of the transistor 237 are within the scope of the present disclosure.

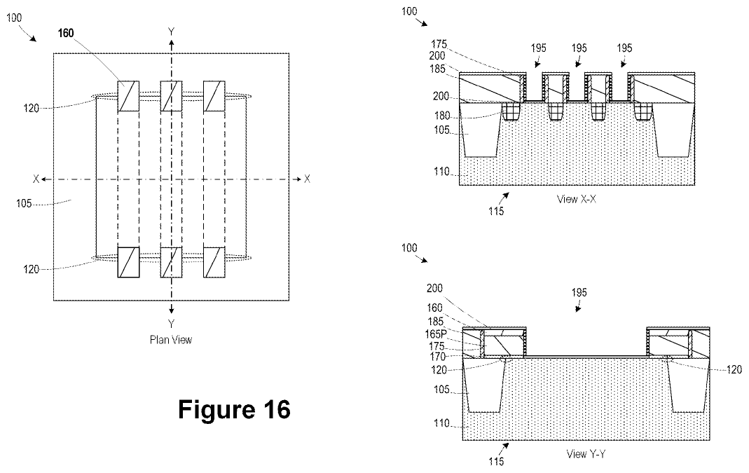

FIGS. 16-19 illustrate the semiconductor arrangement 100 at various stages of fabrication where merely portions of the gate electrodes 165 are replaced. The fabrication illustrated in FIG. 16 starts with the semiconductor arrangement 100 illustrated in FIG. 9 after formation of the first gate cavities 195.

Referring to FIG. 16, the mask 190 is removed and gate dielectric layer 200 is formed over the dielectric layer 185 and in the first gate cavities 195, in accordance with some embodiments. In some embodiments, the gate dielectric layer 200 comprises a high-k dielectric layer comprising suitable materials described above.

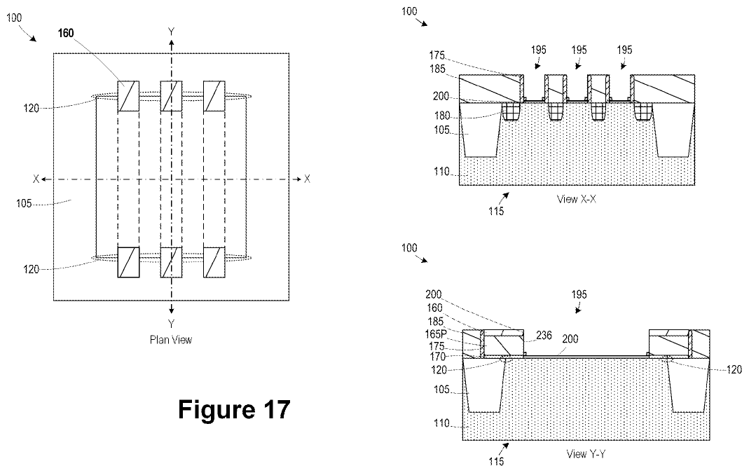

Referring to FIG. 17, the gate dielectric layer 200 is removed such that merely portions of the gate dielectric layer 200 remain in the first gate cavities 195, according to some embodiments. In some embodiments, a chamfering process is performed to remove the portions of the gate dielectric layer 200 positioned on the sidewalls 236 of the gate electrode portions 165P and the portions of the gate dielectric layer 200 positioned over the dielectric layer 185. According to some embodiments, a chamfering process includes depositing a sacrificial material in the first gate cavities 195, performing an etching process selective to the sacrificial material to expose the portions of the gate dielectric layer 200 to be removed, performing an etching process selective to the material of the gate dielectric layer 200 to remove the exposed portions of the gate dielectric layer 200, and performing an etching or ashing process to remove the sacrificial material. Other structures and/or configurations of the gate dielectric layer 200 are within the scope of the present disclosure.

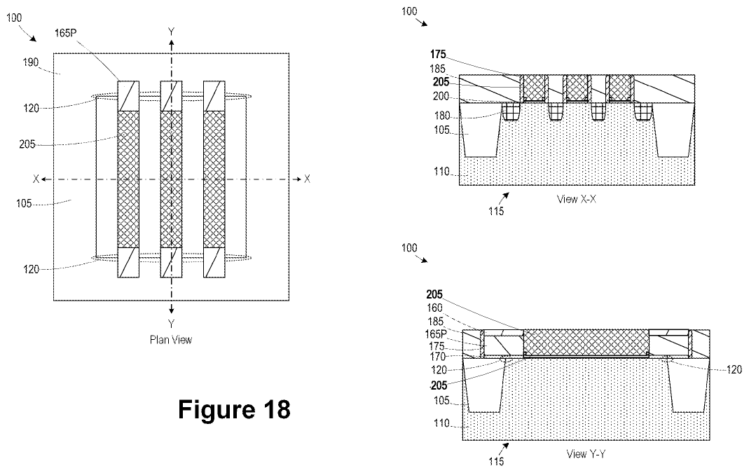

Referring to FIG. 18, gate electrode portions 205 are formed in the first gate cavities 195 over the gate dielectric layer 200, in accordance with some embodiments. In some embodiments, the gate electrode portions 205 comprise suitable layers in a metal gate stack as described above. Other structures and/or configurations of the gate electrode portions 205 are within the scope of the present disclosure.

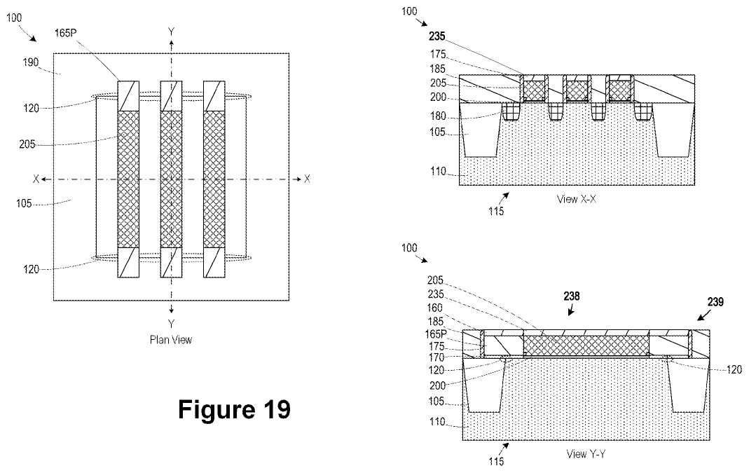

Referring to FIG. 19, cap layers 235 are formed over the gate electrode portions 205 and the gate electrode portions 165P, according to some embodiments. In some embodiments, an etching process is performed to recess the gate electrode portions 205 and the gate electrode portions 165P, a deposition process is performed to form the cap layers 235, and a planarization process is performed to remove portions of the cap layers 235 over the dielectric layer 185. In some embodiments, the cap layers 235 comprise silicon, nitrogen, oxygen, and/or other suitable materials. Other structures and/or configurations of the cap layers 235 are within the scope of the present disclosure. For ease of illustration the cap layers 235 are omitted from the plan view.

Similar to the discussion with respect to FIG. 15, a transistor 238 in FIG. 19, according to some embodiments, generally comprises the active region 115 bounded by the STI structure 105, the source/drain regions 180, and a gate electrode 239 comprising a gate electrode portion 165P over an interface 120 between the active region 115 and the isolation structure and a gate electrode portion 205 over the active region 115. A transistor is also regarded as having multiple gate electrodes according to some embodiments. Current flow is similar to the discussion with respect to FIG. 15.

According to some embodiments, the work function of the gate electrode portions 205 is tailored to the conductivity type of transistor 238, and the gate electrode portions 165P are undoped or doped with an impurity of opposite conductivity type, in accordance with some embodiments. For example, if the transistor 238 comprises an n-type device, the gate electrode portions 205 comprise materials having an n-type work function, and the gate electrode portions 165P comprise materials that are undoped or doped with a p-type impurity. Conversely, if the transistor 238 comprises a p-type device, the gate electrode portions 205 comprise materials having a p-type work function, and the gate electrode portions 165P comprise materials that are undoped or doped with an n-type impurity. In some embodiments, the semiconductor arrangement 100 comprises both n-type and p-type transistors 238. Similar to the discussion with respect to FIG. 15, the material types and thus work functions are selected to inhibit current flow near the interface 120. Other structures and/or configurations of the transistor 238 are within the scope of the present disclosure.

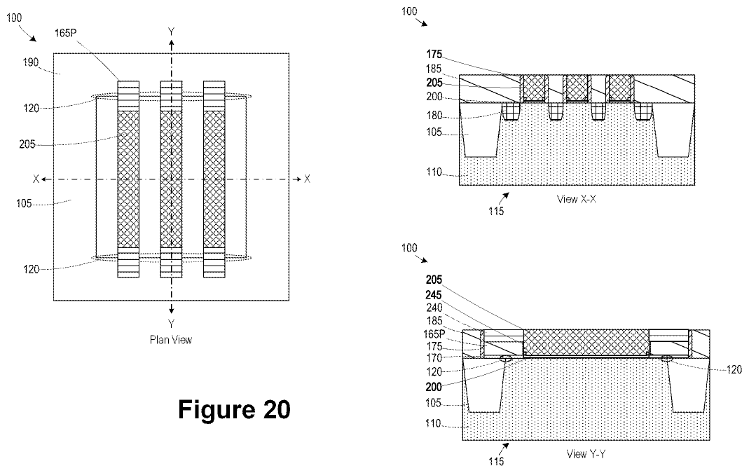

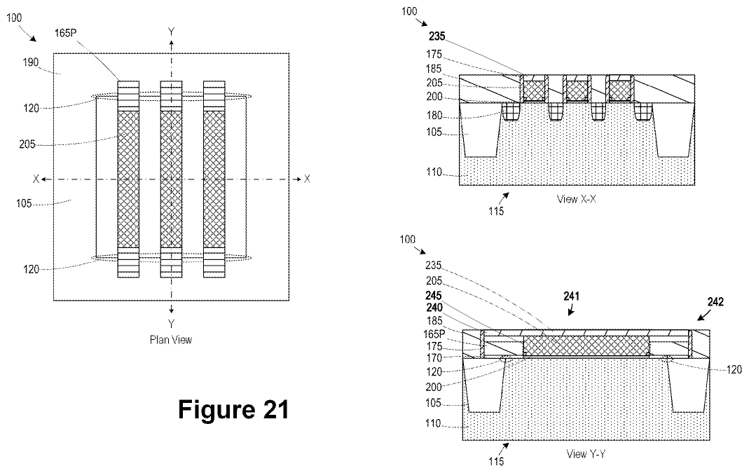

FIGS. 20-21 illustrate the semiconductor arrangement 100 at various stages of fabrication where merely portions of the gate electrodes 165 are replaced. The fabrication illustrated in FIG. 20 starts with the semiconductor arrangement 100 illustrated in FIG. 18 after formation of the gate electrode portions 205.

Referring to FIG. 20, the cap layers 235 are removed and silicide layers 240 are formed on upper surfaces of the gate electrode portions 165P, in accordance with some embodiments. In some embodiments, the silicide layers 325A, 325B are formed by depositing a conformal layer of a refractory metal over the semiconductor arrangement 100. The refractory metal comprises at least one of Ti, Ni, Co, Pd, Pt, or other suitable materials, according to some embodiments. In some embodiments, silicides comprising Ti have n-type work functions, and silicides comprising Ni, Co, Pt, or Pd have p-type work functions. An annealing process is performed to cause the refractory metal to react with underlying silicon-containing material in the gate electrode portions 165P to form a metal silicide, and an etch process is performed to remove unreacted portions of the layer of refractory metal, according to some embodiments. In some embodiments, an additional annealing process is performed to form a final phase of the metal silicide. The silicide formation process consumes some of the material of the gate electrode portions 165P, according to some embodiments. In some embodiments, a dielectric layer, such as a native oxide layer 245 (indicated by dashed line), forms on the gate electrode portions 165P after the chamfering of the gate dielectric layer 200, and the process for forming the silicide layers 240 deoxidizes the native oxide layer 245 such that the silicide layers 240 directly contact the gate electrode portions 205. In some embodiments, the silicide layers 240 have a work function of opposite conductivity type compared to the work function conductivity type of the gate electrode portions 205. For example, in an embodiment where the WFM of the gate electrode portions 205 is p-type, the work function of the silicide layers 240 n-type. Conversely, in an embodiment where the WFM of the gate electrode portions 205 is n-type, the WFM of the silicide layers 240 is p-type. Other structures and/or configurations of the silicide layers 240 are within the scope of the present disclosure.

Referring to FIG. 21, cap layers 235 are formed over the gate electrode portions 205 and the silicide layers 240, according to some embodiments. In some embodiments, an etching process is performed to recess the gate electrode portions 205 and the silicide layers 240, a deposition process is performed to form the cap layers 235, and a planarization process is performed to remove portions of the cap layers 235 over the dielectric layer 185. In some embodiments, the cap layers 235 comprise silicon, nitrogen, oxygen, and/or other suitable materials. Other structures and/or configurations of the cap layers 235 are within the scope of the present disclosure. For ease of illustration, the cap layers 235 are omitted in the plan view.

Similar to the discussion with respect to FIG. 15, a transistor 241 in FIG. 21, according to some embodiments, generally comprises the active region 115 bounded by the STI structure 105, the source/drain regions 180, and a gate electrode 242 comprising a gate electrode portion 165P comprising a silicide layer 240 and positioned over an interface 120 between the active region 115 and the isolation structure and a gate electrode portion 205 over the active region 115. A transistor is also regarded as having multiple gate electrodes according to some embodiments. Current flow is similar to the discussion with respect to FIG. 15.

According to some embodiments, the gate electrode portions 250 are doped with an impurity corresponding to the conductivity type of the transistor 241, and the gate electrode portions 165P are undoped or doped with an impurity having a conductivity type opposite to the device conductivity type, in accordance with some embodiments. For example, if the transistor 241 comprises an n-type device, the gate electrode portions 250 comprise materials doped with an n-type impurity, the gate electrode portions 165P are undoped or comprise materials doped with a p-type impurity, and the silicide layers 240 have p-type work functions. Conversely, if the transistor 241 comprises a p-type device, the gate electrode portions 250 comprise materials doped with an p-type impurity, the gate electrode portions 165P are undoped or comprise materials doped with an n-type impurity, and the silicide layers 240 have n-type work functions. In some embodiments, the semiconductor arrangement 100 comprises both n-type and p-type transistors 241. Similar to the discussion with respect to FIG. 15, the material types and thus work functions are selected to inhibit current flow near the interface 120. Other structures and/or configurations of the transistor 241 are within the scope of the present disclosure.

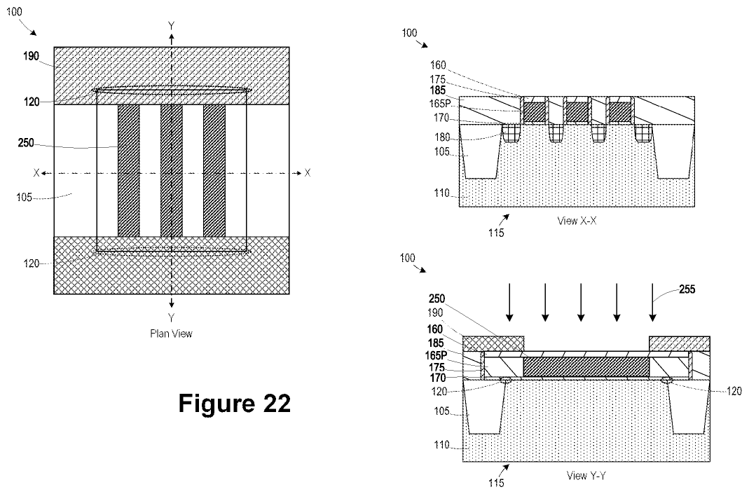

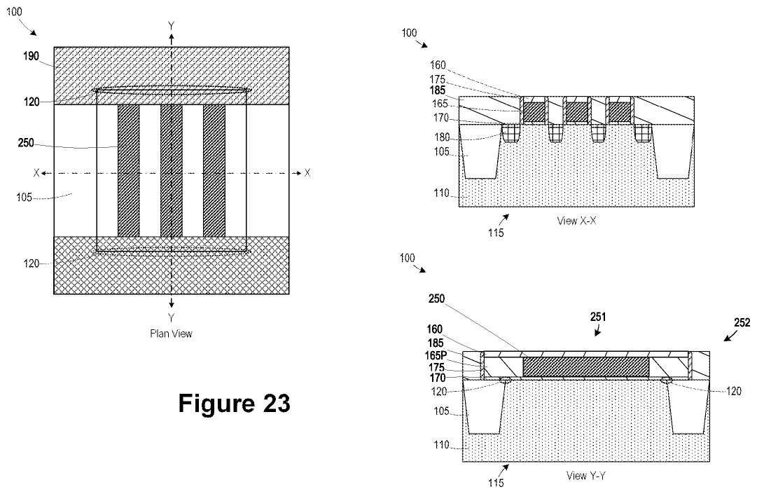

FIGS. 22-23 illustrate the semiconductor arrangement 100 at various stages of fabrication where the gate electrodes 165 are not replaced. The fabrication illustrated in FIG. 22 starts with the semiconductor arrangement 100 illustrated in FIG. 8 after formation of the mask 190.

Referring to FIG. 22, gate electrode portions 250 doped with an impurity are formed in a portion of the gate electrodes 165, in accordance with some embodiments. In some embodiments, an implantation process 255 is performed using the mask 190 as an implantation template to implant the impurity into the exposed portion of the gate electrode 165 to form the gate electrode portions 250 and define the remaining gate electrode portions 165P.

Referring to FIG. 23, the mask 190 is removed, in accordance with some embodiments. Similar to the discussion with respect to FIG. 15, a transistor 251 in FIG. 23, according to some embodiments, generally comprises the active region 115 bounded by the STI structure 105, the source/drain regions 180, and a gate electrode 252 comprising a gate electrode portion 165P over an interface 120 between the active region 115 and the isolation structure and a gate electrode portion 250 over the active region. A transistor is also regarded as having multiple gate electrodes according to some embodiments. Current flow is similar to the discussion with respect to FIG. 15.

The impurity conductivity type is tailored to the conductivity type of the transistor 251. For example, if the transistor 251 comprises an n-type device, the gate electrode portions 250 are doped with an n-type impurity and the gate electrode portions 165P comprise materials that are undoped or doped with a p-type impurity. Conversely, if the transistor 251 comprises a p-type device, the gate electrode portions 250 are doped with a p-type impurity and the gate electrode portions 165P comprise materials that are undoped or doped with an n-type impurity. In some embodiments, the semiconductor arrangement 100 comprises both n-type and p-type transistors 251. Similar to the discussion with respect to FIG. 15, the material types and thus work functions are selected to inhibit current flow near the interface 120. Other structures and/or configurations of the transistor 241 are within the scope of the present disclosure.

As provided herein, the gate electrode portions 165P, 230 over the interfaces 120 between the active region 115 and the STI structure 105 have different material compositions than the material compositions of the gate electrode portions 205, 250 over the active region 115, according to some embodiments. In some embodiments, the different material compositions result in the gate electrode portions 165P, 230 having a material with a work function different than the work function of the material of the gate electrode portions 205, 250 over the active region 115. The different work functions may be of different conductivity types, according to some embodiments. In some embodiments, gate contacts are subsequently formed to contact the gate electrodes 239, 242, 252. In some embodiments, the gate contacts are formed to contact the gate electrode portions 165P, 230 over the interfaces 120 between the active region 115 and the STI structure 105. In some embodiments, gate contacts to the gate electrode portions 165P, 230 are formed on one end of the gate electrodes 239, 242, 252 to contact the gate electrode portions 165P, 230 or on both ends of the gate electrodes 239, 242, 252.

In some embodiments, electrons are trapped at the interface 120 between the STI structure 105 and the active region 115 which results in noise and/or other undesirable issues. Non-uniform compressive stress induced by the STI structure 105 contributes to the trapping of the electrons. These trapped electrons can introduce noise in the form of random telegraph signals or flicker in a signal propagating through the transistor 237, 238, 241, 251. Increasing the number of gate electrodes 239, 242, 252 generally results in an increase in the level of noise. Due to the different material compositions of the gate electrode portions 165P, 230 over the interfaces 120 between the active region 115 and the STI structure 105 and the material compositions of the gate electrode portions 205, 250 over the active region 115 the electromagnetic field generated by the gate electrodes 239, 242, 252 varies in the portion over the interface 120, thereby reducing the current density in the active region 115 near the interface 120 compared to the current density in the active region 115 under the gate electrode portions 205, 250. This reduced current density reduces the noise generated by trapped electrons at the interface 120, thereby improving the performance of the transistor 237, 238, 241, 251.

In some embodiments, a semiconductor arrangement includes a gate electrode. The gate electrode includes a first portion over a first interface between an active region and an isolation structure and a second portion over the active region. The first portion has a first material composition. The second portion has a second material composition different than the first material composition.

In some embodiments, a semiconductor arrangement includes a gate electrode. The gate electrode includes a first portion over a first interface between an active region and an isolation structure and a second portion over the active region. The active region includes a first impurity having a first conductivity type. The first portion has a first work function. The second portion has a second work function different than the first work function. The second work function has the first conductivity type.

In some embodiments, a method of forming a semiconductor arrangement includes forming a first gate electrode over an active region and an isolation structure. The first gate electrode is modified to form a first gate electrode portion over a first interface between the active region and the isolation structure and a second gate electrode portion over the active region. The first gate electrode portion has a first material composition. The second gate electrode portion has a second material composition different than the first material composition.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor arrangement, comprising:
a gate electrode, comprising:
a first portion over a first interface between an active region and an isolation structure; and
a second portion over the active region, wherein:
the first portion has a first material composition; and
the second portion has a second material composition different than the first material composition.

2. The semiconductor arrangement of claim 1, wherein:
the first material composition has a first work function; and
the second material composition has a second work function different than the first work function.

3. The semiconductor arrangement of claim 1, wherein:
the first material composition has a first work function type; and
the second material composition has a second work function type opposite the first work function type.

4. The semiconductor arrangement of claim 1, wherein:
the first material composition comprises a first metal; and
the second material composition comprises a second metal different than the first metal.

5. The semiconductor arrangement of claim 1, wherein:
the first material composition comprises silicon; and
the second material composition comprises a first metal having a first work function with a first conductivity type.

6. The semiconductor arrangement of claim 5, wherein:
the first material composition comprises an impurity having a second conductivity type opposite the first conductivity type.

7. The semiconductor arrangement of claim 5, wherein:
the first portion comprises a silicide having a second work function with a second conductivity type opposite the first conductivity type.

8. The semiconductor arrangement of claim 1, comprising:
a dielectric layer between the first portion and the second portion.

9. The semiconductor arrangement of claim 1, wherein:
the first material composition comprises silicon and a first impurity having a first conductivity type; and
the second material composition comprises silicon and a second impurity having a second conductivity type opposite the first conductivity type.

10. A semiconductor arrangement, comprising:
a gate electrode, comprising:
a first portion over a first interface between an active region and an isolation structure; and
a second portion over the active region, wherein:
the active region comprises a first impurity having a first conductivity type;
the first portion has a first work function;
the second portion has a second work function different than the first work function; and
the second work function has the first conductivity type.

11. The semiconductor arrangement of claim 10, wherein the first work function has a second conductivity type opposite the first conductivity type.

12. A method for forming a semiconductor arrangement, comprising:
forming a first gate electrode over an active region and an isolation structure;
modifying the first gate electrode to form a first gate electrode portion over a first interface between the active region and the isolation structure and a second gate electrode portion over the active region, wherein:
the first gate electrode portion has a first material composition; and
the second gate electrode portion has a second material composition different than the first material composition.

13. The method of claim 12, wherein modifying the first gate electrode comprises:
replacing a first portion of the first gate electrode with a first metal having a first work function to define the first gate electrode portion; and
replacing a second portion of the first gate electrode with a second metal having a second work function different than the first work function to define the second gate electrode portion.

14. The method of claim 12, wherein modifying the first gate electrode comprises:
replacing a first portion of the first gate electrode with a first metal to define the second gate electrode portion.

15. The method of claim 14, wherein:
the first gate electrode portion comprises silicon.

16. The method of claim 14, wherein:
the first gate electrode portion comprises silicon and a first impurity having a first conductivity type; and
the first metal has a work function with a second conductivity type opposite the first conductivity type.

17. The method of claim 14, wherein modifying the first gate electrode comprises:
forming a silicide layer in a second portion of the first gate electrode different than the first portion to define the first gate electrode portion, wherein:
the silicide layer has a first work function with a first conductivity type; and
the first metal has a second work function with a second conductivity type opposite the first conductivity type.

18. The method of claim 17, wherein forming the silicide layer in the second portion of the first gate electrode comprises:
deoxidizing a dielectric material between the second portion of the first gate electrode and the first metal.

19. The method of claim 12, wherein modifying the first gate electrode comprises:
providing a first impurity in a first portion of the first gate electrode to define the second gate electrode portion.

20. The method of claim 19, wherein modifying the first gate electrode comprises:
providing a second impurity in a second portion of the first gate electrode to define the first gate electrode portion, wherein:
the first impurity has a first conductivity type; and
the second impurity has a second conductivity type opposite the first conductivity type.
